(19) United States
(12) Patent Application Publication
(10) Pub. No.: US 2026/0100224 A1
(43) Pub. Date: Apr. 9, 2026

(54) CONTENT ADDRESSABLE MEMORY AND SEMICONDUCTOR DEVICE

(71) Applicant: Renesas Electronics Corporation, Tokyo (JP)

(72) Inventors: Daiki KITAGATA, Tokyo (JP); Kenichiro TAKIGUCHI, Tokyo (JP); Shinji TANAKA, Tokyo (JP)

(21) Appl. No.: 19/331,008

(22) Filed: Sep. 17, 2025

(30) Foreign Application Priority Data
Oct. 4, 2024 (JP) 2024-174875

(51) Int. Cl. G11C 15/04; G11C 16/26; G11C 16/32

(52) U.S. Cl. CPC G11C 15/046; G11C 16/26; G11C 16/32

(57) ABSTRACT

A content addressable memory includes a cell array capable of storing a plurality of data entries, a plurality of valid cells provided for each of the data entries and configured to store valid bits indicating valid or invalid of the data entry, an All-invalid detection circuit configured to detect that the plurality of valid bits all indicate invalid, a search unit configured to determine matching or mismatching between the plurality of data entries and search data, and a control unit configured to stop the search unit when the All-invalid detection circuit detects that the valid bits all indicate invalid.

### CROSS-REFERENCE TO RELATED APPLICATIONS

The disclosure of Japanese Patent Application No. 2024-174875 filed on October 4, 2024 including the specification, drawings and abstract is incorporated herein by reference in its entirety.

### BACKGROUND

The present invention relates to a content addressable memory and a semiconductor device, for example, a semiconductor device having a content addressable memory with a function of determining the matching between a plurality of data entries and search data.

A storage device referred to as a search memory or a content addressable memory (CAM) searches stored data words (referred to also as data entries) for a word matching with a search word (search data) and outputs an address thereof when the matching data word is found.

The CAM includes a BCAM (Binary CAM) and a TCAM (Ternary CAM). Each memory cell of the BCAM stores information of either “0” or “1”. On the other hand, in the case of the TCAM, each memory cell can store information of “Don’t Care” in addition to “0” and “1”. “Don’t Care” indicates that either “0” or “1” will do.

The TCAM has been widely used for the address search and the access control in a router for a network such as Internet.

There is disclosed a technique listed below.

[Patent Document 1] Japanese Unexamined Patent Application Publication No. 2018-206451

Patent Document 1 describes that a content addressable memory has a valid cell, which stores a valid bit indicating whether a data entry is valid or invalid, for each data entry.

### SUMMARY

The valid bit (valid cell) described in Patent Document 1 indicates whether a data entry is valid or invalid, and the power consumption of match line precharge or the like can be reduced by excluding the data entry whose valid bit is invalid from the target of the search operation. On the other hand, since a search line to which search data is supplied spans across a plurality of data entries, the search operation cannot be stopped if there is even one data entry whose valid bit indicates valid.

The embodiments to be described below have been made in consideration of the above circumstances, and other problems and novel features will be apparent from the description of this specification and accompanying drawings.

A content addressable memory according to one embodiment includes a cell array capable of storing a plurality of data entries, a valid cell provided for each of the data entries and configured to store information indicating valid or invalid of the data entry, an invalid detection unit configured to detect that the information all indicates invalid, a first search unit configured to determine matching or mismatching between the plurality of data entries and search data input from outside, and a control unit configured to stop the first search unit when the invalid detection unit detects that the information all indicates invalid.

According to the above embodiment, it is possible to reduce the power consumption of a content addressable memory.

### BRIEF DESCRIPTION OF THE DRAWINGS

FIG. 1 is a schematic diagram of a conventional content addressable memory.

FIG. 2 is a schematic configuration diagram of a content addressable memory according to the first embodiment.

FIG. 3 is a circuit diagram of a main part of the content addressable memory in FIG. 2.

FIG. 4 is a circuit diagram of a timing generation circuit.

FIG. 5 is a diagram of a valid cell.

FIG. 6 is a circuit diagram of a BL/SL Driver.

FIG. 7 is a circuit diagram of a match line output circuit.

FIG. 8 is a circuit diagram of an All-invalid detection circuit.

FIG. 9 is a flowchart illustrating an operation of the content addressable memory according to the first embodiment.

FIG. 10 is a schematic diagram of a semiconductor device provided with a plurality of content addressable memories.

FIG. 11 is a circuit diagram of a timing generation circuit according to the second embodiment.

FIG. 12 is a flowchart illustrating an operation of a content addressable memory according to the second embodiment.

FIG. 13 is a schematic diagram of a semiconductor device according to the third embodiment.

FIG. 14 is a schematic diagram illustrating an application example of the embodiment.

### DETAILED DESCRIPTION

In the following embodiments, when necessary for convenience, the invention will be described in a plurality of sections or embodiments, but the sections or embodiments are not irrelevant to each other unless otherwise specified, and one is in a relationship of modification, details, supplementary description, and the like of a part or all of the other. In addition, in the following embodiments, when referring to the number of elements and the like (including number, numerical value, amount, range, and the like), the number is not limited to a specific number unless otherwise specified or clearly limited to the specific number in principle, and the number may be equal to or more than or less than the specific number.

Furthermore, in the following embodiments, it goes without saying that the components (including element steps and the like) are not necessarily essential unless otherwise specified or considered to be obviously essential in principle. Similarly, in the following embodiments, when referring to the shape, positional relationship, and the like of the components and the like, it is assumed to include those substantially approximate or similar to the shape and the like unless otherwise specified or unless clearly considered otherwise in principle. The same applies to the above numerical value and range.

Also, circuit elements constituting each functional block of the embodiments are not particularly limited, but are formed on a semiconductor substrate such as a single crystal silicon substrate by a publicly known integrated circuit technology for complementary MOS transistors (CMOS) or the like. In the embodiments, metal oxide semiconductor field effect transistors (MOSFETs abbreviated as MOS transistors) are used as an example of metal insulator semiconductor field effect transistors (MISFETs), but this does not exclude the use of non-oxide films as gate insulating films. Further, in the embodiments, p channel MOSFETs and n channel MOSFETs are referred to as pMOS transistors and nMOS transistors, respectively.

Hereinafter, embodiments of the present invention will be described in detail with reference to the drawings. Note that, in all the drawings for describing the embodiments, the same members are denoted by the same reference characters in principle, and repetitive description thereof will be omitted.

### First embodiment

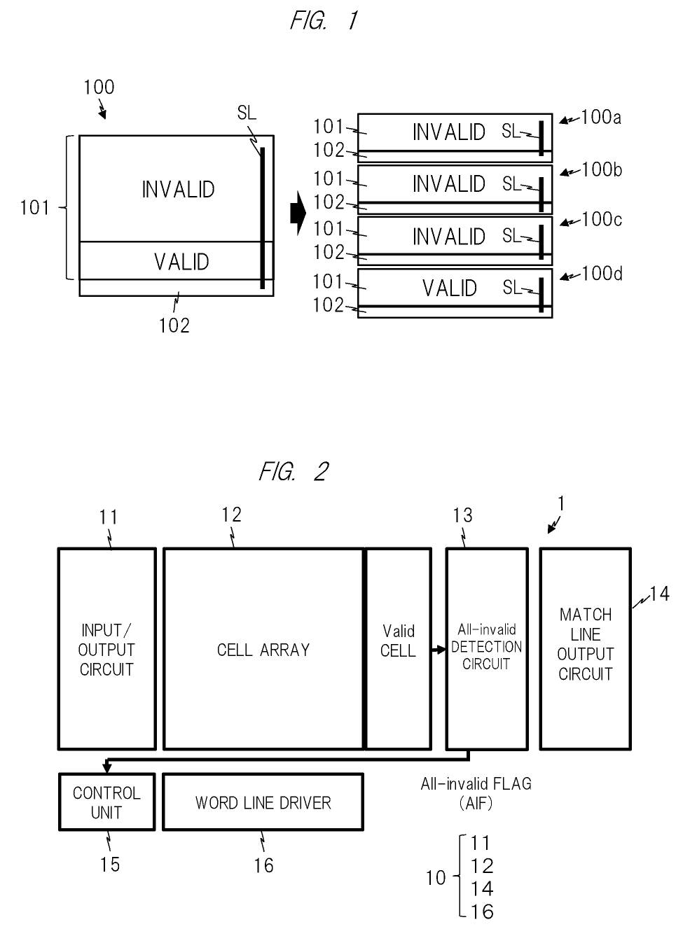

FIG. 1 illustrates a schematic diagram of a semiconductor device according to this embodiment. In this embodiment, a content addressable memory in which a search operation is executed in a row direction to cell arrays including a plurality of TCAM cells, which are arranged in a matrix and configured to store data entries (hereinbelow, abbreviated as entries in some cases) made up of bit strings composed of a plurality of bits, will be described.

### Problems to be solved by this embodiment

As described above, although measures to reduce the power consumption of match line precharge or the like have been conventionally taken, the search line spans across a plurality of entries as illustrated on the left side of FIG. 1, so the search operation cannot be stopped if there is even one entry whose valid bit indicates valid. FIG. 1 is a schematic diagram of a conventional content addressable memory 100, in which a reference character 101 denotes a cell array, a reference character 102 denotes a peripheral circuit such as a control unit, and a reference character SL denotes a search line. The cell array 101 includes TCAM cells in which data to be an entry is stored and valid cells mentioned above. The peripheral circuit 102 controls writing and reading to and from the cell array 101, and performs a matching determination between input search data and a data entry stored in the TCAM cell or the like.

Conventionally, as illustrated on the left side of FIG. 1, the content addressable memory 100 is configured to have one cell array 101 (for example, a capacity of 1 Mbit). This is because increase in area of the peripheral circuit 102 is large when the cell array 101 is divided into, for example, four parts each having 256 bits and priority is given to area saving.

In recent years, however, there has been a demand for a content addressable memory to operate at higher frequency than before, and a configuration having a plurality of divided content addressable memories is sometimes used in order to meet this demand (right side of FIG. 1). The right side of FIG. 1 is a schematic diagram of the configuration including a plurality of divided content addressable memories. Reference characters 100a, 100b, 100c, and 100d on the right side of FIG. 1 denote divided content addressable memories, respectively, and the four content addressable memories 100a, 100b, 100c, and 100d combined together have the same capacity as the content addressable memory illustrated on the left side.

In the case of FIG. 1, in the configuration made up of one cell array 101 illustrated on the left side, if data of even one entry is written, validity and invalidity of the valid bits of the cell array 101 are mixedly present, so the search operation cannot be stopped. However, by dividing the cell array into a plurality of cell arrays 101 as illustrated on the right side, there may be a content addressable memory in which data entries stored in one cell array 101 are all invalid. For example, if valid data entry is sequentially written starting from a specific content addressable memory, content addressable memories to which data have not yet been written are all invalid. In the case of FIG. 1, the content addressable memory 100d has a data entry whose valid bit is valid, but the valid bits of the content addressable memories 100a, 100b, and 100c are all invalid. Therefore, the content addressable memories 100a, 100b, and 100c consume unnecessary power during search operations because no valid data is stored therein.

### Schematic configuration of this embodiment

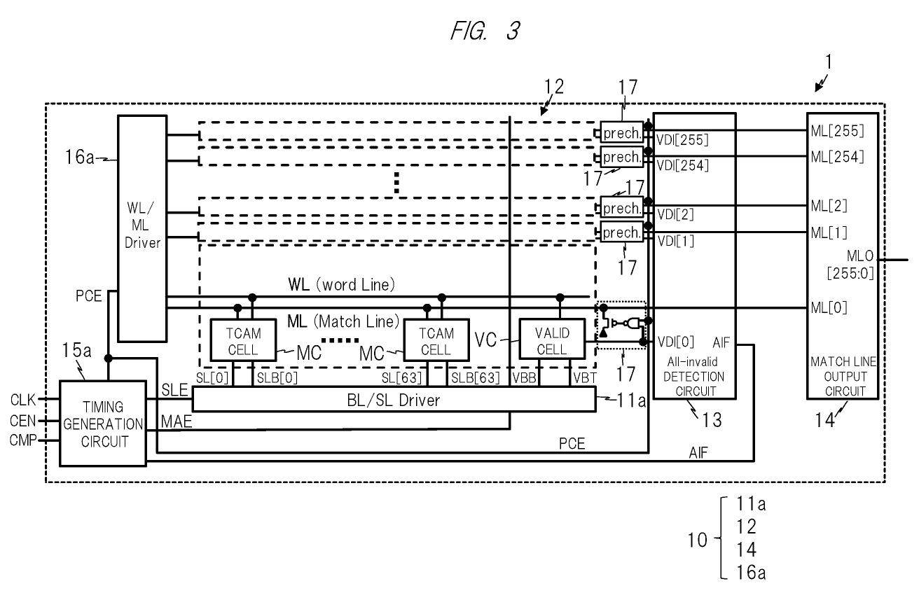

The content addressable memory according to this embodiment will be described with reference to FIG. 2. A content addressable memory 1 includes an input/output circuit 11, a cell array 12, an All-invalid detection circuit 13, a match line output circuit 14, a control unit 15, and a word line driver 16.

The input/output circuit 11 inputs data to be stored in the cell array 12 and outputs read data. The input/output circuit 11 also receives search data for determining the matching with the data (data entries) stored in the cell array 12.

The cell array 12 includes TCAM cells that store data to be data entries and valid cells that store valid bits, which are information indicating whether each data entry is valid or invalid. In other words, the cell array 12 can store a plurality of data entries, and further includes valid cells provided for each data entry and storing information indicating whether the data entry is valid or invalid.

The All-invalid detection circuit 13 detects whether the valid bits stored in all the valid cells indicate invalid. In other words, the All-invalid detection circuit 13 functions as an invalid detection unit that detects that all the valid bits indicate invalid. The match line output circuit 14 bundles and outputs the match lines output from the cell array 12 for each data entry. The control unit 15 includes a timing generation circuit and the like to be described later, and controls the operation of the content addressable memory 1. The word line driver 16 drives the word lines for accessing the TCAM cells of the cell array 12.

In the content addressable memory 1 illustrated in FIG. 2, the input/output circuit 11, the cell array 12, the match line output circuit 14, and the word line driver 16 mentioned above constitute a search unit 10. In other words, the search unit 10 functions as a first search unit that determines matching or mismatching between a plurality of data entries and the search data.

### Circuit example of this embodiment

Next, a circuit example of the content addressable memory 1 will be described with reference to FIG. 3 to FIG. 8. Note that the circuits illustrated below are examples, and it goes without saying that other circuit configurations may be used as long as they can achieve the same functions. In addition, the logic levels indicating assertion and negation of each signal may also be changed as appropriate. FIG. 3 illustrates a circuit example of the main part of the content addressable memory 1.

A BL/SL Driver 11a illustrated in FIG. 3 corresponds to the input/output circuit 11 illustrated in FIG. 2. The BL/SL Driver 11a illustrates only the part related to the search line SL that inputs the search data, in the functions of the input/output circuit 11. Similarly, a timing generation circuit 15a illustrated in FIG. 3 corresponds to the control unit 15 illustrated in FIG. 2. The timing generation circuit 15a is a circuit that generates control signals related mainly to the search operation, in the functions of the control unit 15. Similarly, a WL/ML Driver 16a illustrated in FIG. 3 corresponds to the word line driver 16 illustrated in FIG. 2. The WL/ML Driver 16a includes a circuit that drives a match line that indicates whether an entry matches the search data, in addition to a circuit that drives the word line.

The cell array 12 includes a plurality of TCAM cells MC arranged in a matrix. Also, one valid cell VC is provided for each row (each entry). Further, a word line WL and a match line ML are provided along the row direction, and search line pairs SL, SLB are provided along the column direction. Namely, one word line WL and one match line ML are provided for each entry, and the search line is provided spanning across a plurality of entries.

A reference character 17 in FIG. 3 denotes a precharge circuit. The precharge circuit 17 includes a two-input NAND circuit and a pMOS transistor. An output signal of the valid cell VC and a control signal PCE are input to the two-input NAND circuit. A source of the pMOS transistor is connected to the match line ML, a drain thereof is connected to Vdd, and a gate thereof is connected to an output of the two-input NAND circuit. The precharge circuit 17 is provided for each entry (match line ML). The control signal PCE is generated by the timing generation circuit 15a as described later, and is asserted during the search operation. The precharge circuit 17 precharges the match line ML during the search operation according to the value of the valid cell VC.

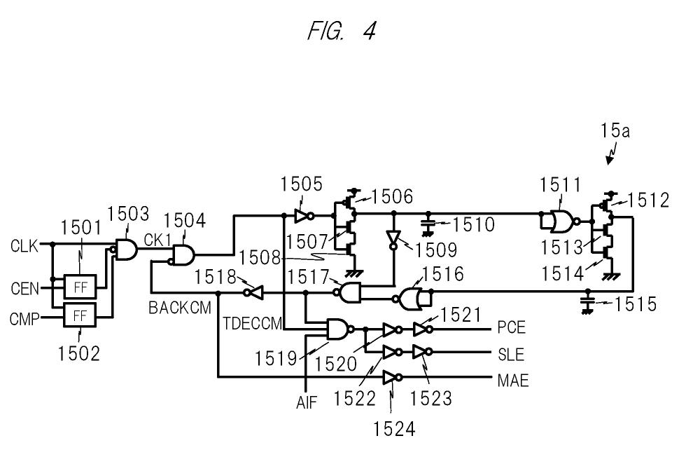

FIG. 4 is an example of a circuit diagram of the timing generation circuit 15a. The timing generation circuit 15a is a circuit that generates the control signal PCE, a control signal MAE, and a control signal SLE in response to the clock signal CLK. In the circuit of FIG. 4, when a control signal AIF is input, the assertion of the control signals PCE and SLE is stopped. As described later, the control signal AIF is an output signal of the All-invalid detection circuit 13, and the control signals PCE and SLE are signals that are asserted during the search operation. Therefore, when the All-invalid detection circuit 13 detects that all the valid bits indicate invalid, the timing generation circuit 15a stops the search unit 10.

The timing generation circuit 15a includes flip-flops 1501 and 1502, AND circuits 1503 and 1504, inverters 1505, 1509, 1518, 1520, 1521, 1522, 1523, and 1524, pMOS transistors 1506 and 1512, nMOS transistors 1507, 1508, 1513, and 1514, capacitance elements 1510 and 1515, NOR circuits 1511 and 1516, and NAND circuits 1517 and 1519.

The flip-flop 1501 takes in and outputs a control signal CEN based on the clock signal CLK. The control signal CEN is a chip enable signal and is a control signal that controls validity and invalidity of the clock signal CLK. The flip-flop 1502 takes in and outputs a control signal CMP based on the clock signal CLK. The control signal CMP is a search request signal.

The AND circuit 1503 receives the clock signal CLK, an inverted signal of the output of the flip-flop 1501, and the output signal of the flip-flop 1502, and outputs the result of AND logic operation (control signal CK1). The AND circuit 1504 receives the control signal CK1 and the inverted signal of the output of inverter 1518, and outputs the result of AND logic operation (control signal TDECCM).

The inverter 1505 inverts the control signal TDECCM and outputs it to a gate of the pMOS transistor 1506, a gate of the nMOS transistor 1507, and a gate of the nMOS transistor 1508.

The pMOS transistor 1506 and the nMOS transistors 1507 and 1508 are connected in series between the power supply potential (voltage Vdd level) and the ground potential (voltage Vss level). A control signal is output from the connection node between the pMOS transistor 1506 and the nMOS transistor 1507.

The inverter 1509 inverts the control signal output from the connection node between the pMOS transistor 1506 and the nMOS transistor 1507 and outputs it.

The NOR circuit 1511 inverts the control signal output from the connection node between the pMOS transistor 1506 and the nMOS transistor 1507 and outputs it to a gate of the pMOS transistor 1512, a gate of the nMOS transistor 1513, and a gate of the nMOS transistor 1514. Also, the capacitance element 1510, the other electrode of which is connected to the ground potential (voltage Vss level), is connected to an input node of the NOR circuit 1511.

The pMOS transistor 1512 and the nMOS transistors 1513 and 1514 are connected in series between the power supply potential and the ground potential. A control signal is output from the connection node between the pMOS transistor 1512 and the nMOS transistor 1513.

The NOR circuit 1516 inverts the control signal output from the connection node between the pMOS transistor 1512 and the nMOS transistor 1513 and outputs it. In addition, the capacitance element 1515, the other electrode of which is connected to the ground potential, is connected to an input node of the NOR circuit 1516.

The NAND circuit 1517 receives the output signal of the NOR circuit 1516 and the output signal of the inverter 1509, and outputs the result of NAND logic operation. The inverter 1518 inverts the output signal of the NAND circuit 1517 and outputs it (control signal BACKCM).

The NAND circuit 1519 receives the control signal TDECCM, the output signal of the NAND circuit 1517, and the control signal AIF, and outputs the result of NAND logic operation. The inverters 1520 and 1521 output the output of the NAND circuit 1519 as the control signal PCE.

The inverters 1522 and 1523 output the output signal of the NAND circuit 1519 as the control signal SLE. The inverter 1524 inverts the control signal BACKCM and outputs it as the control signal MAE.

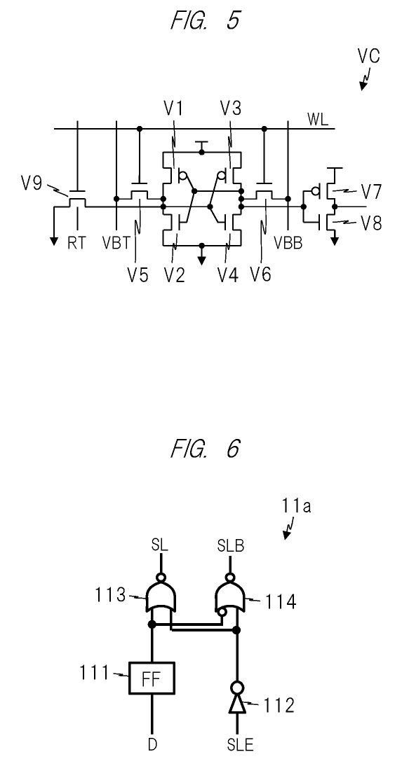

FIG. 5 is an example of a circuit of the valid cell VC. The valid cell VC includes pMOS transistors V1, V3, and V7 and nMOS transistors V2, V4, V5, V6, V8, and V9.

The pMOS transistor V1 and the nMOS transistor V2 are connected in series between, for example, the power supply potential Vdd and the power supply potential Vss to form an inverter (hereinbelow, referred to as a first inverter for identification). Also, the pMOS transistor V3 and the nMOS transistor V4 are connected in series between, for example, the power supply potential Vdd and the power supply potential Vss to form an inverter (hereinbelow, referred to as a second inverter for identification). Further, an output of the first inverter is connected to an input of the second inverter, and an output of the second inverter is connected to an input of the first inverter.

A source and a drain of the nMOS transistor V5 are connected between the output of the first inverter and a bit line VBT. Also, a gate of the nMOS transistor V5 is connected to the word line WL. A source and a drain of the nMOS transistor V6 are connected between the output of the second inverter and a bit line VBB. Also, a gate of the nMOS transistor V6 is connected to the word line WL. A bit line pair VBT, VBB is wirings shared by each valid cell VC. The word line WL is a wiring shared by the entries (TCAM cells MC) corresponding to the valid cells VC.

The pMOS transistor V7 and the nMOS transistor V8 are connected in series between, for example, the power supply potential Vdd and the power supply potential Vss to form an inverter (hereinbelow, referred to as the third inverter for identification). The output of the second inverter is input to the third inverter. Also, the output of the third inverter is input to the precharge circuit 17 and the All-invalid detection circuit 13 as a valid bit.

A source and a drain of the nMOS transistor V9 are connected between the power supply potential Vss and the input of the second inverter. A gate of the nMOS transistor V9 is connected to a reset signal RT. The reset signal RT is a signal shared by each valid cell VC.

When the word line WL is in a selected state, the valid bit can be written to the valid cell VC by supplying write data to the valid cell VC via the bit line pair VBT, VBB.

FIG. 6 is an example of a circuit of the BL/SL Driver 11a. The BL/SL Driver 11a includes a flip-flop 111, an inverter 112, and NOR circuits 113 and 114. FIG. 6 illustrates a circuit corresponding to one search line pair SL, SLB, and the circuit of FIG. 6 is plurally provided in reality according to the number of bits of the data entry (and search data).

The flip-flop 111 takes in the search data supplied to a data terminal D based on the clock signal CLK, and outputs it to the NOR circuits 113 and 114. The inverter 112 inverts and outputs the control signal SLE.

The NOR circuit 113 receives the output signal of the flip-flop 111 and the output signal of the inverter 112, and outputs the result of NOR logic operation as the search line SL. The NOR circuit 114 receives the inverted signal of the output of the flip-flop 111 and the output signal of the inverter 112, and outputs the result of NOR logic operation as the search line SLB.

The BL/SL Driver 11a is a circuit that asserts the search line pair SL, SLB to each TCAM cell MC. When the control signal SLE becomes Hi, the search data set in the data terminal D is asserted to the search line pair SL, SLB. Therefore, as described in the timing generation circuit 15a, the assertion of the search data is stopped when the assertion of the control signal SLE is stopped by the control signal AIF. In other words, the control unit 15 stops the input of the search data based on the control signal AIF (invalid control signal).

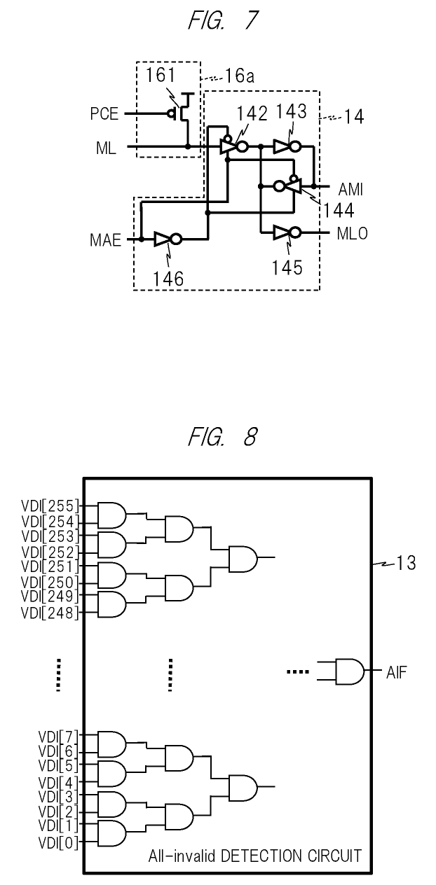

FIG. 7 is an example of the match line output circuit 14. FIG. 7 is a circuit corresponding to one match line ML, and the circuit in FIG. 7 is plurally provided in reality according to the number of match lines ML (number of entries).

The WL/ML Driver 16a includes a pMOS transistor 161. A source and a drain of the pMOS transistor 161 are connected between the power supply potential (voltage Vdd level) and the match line ML. The control signal PCE is connected to a gate of the pMOS transistor 161. The WL/ML Driver 16a is a circuit that drives the match line ML. When the control signal PCE is Lo, the match line ML is precharged, and when the control signal PCE is Hi, the precharge is cut off.

The match line output circuit 14 includes inverters 142, 143, 144, 145, and 146.

When the control signal MAE is input, the inverter 142 outputs an inverted signal of the match line ML. The inverter 143 outputs an inverted signal of the output signal of the inverter 142 or the inverter 144 as an All-Miss determination input AMI. The All-Miss determination input is an input signal for determining whether all the data entries are mismatched (miss) as a result of the search operation.

When the control signal MAE is input, the inverter 144 outputs an inverted signal of the output signal of the inverter 143. When a signal is output from the inverter 142, the inverter 145 outputs an inverted signal of the output signal of the inverter 142 to a match signal output line MLO. Also, when a signal is output from the inverter 144, the inverter 145 outputs an inverted signal of the output signal of inverter 144 to the match signal output line MLO. The inverter 146 outputs an inverted signal of the control signal MAE as a control signal for the inverters 142 and 144.

The control signal MAE is asserted at the timing when the match line ML is determined, and the match line output circuit 14 transmits the data of the match line ML to the match signal output line MLO and the All-Miss determination input AMI.

Described in detail, when the control signal MAE is asserted, the inverter 142 opens and outputs an inverted signal of the match line ML. Meanwhile, the inverter 144 closes and thus does not output a signal. Therefore, when the control signal MAE is asserted, the data of the match line ML is transmitted to the match signal output line MLO and the All-Miss determination input AMI. When the control signal MAE is negated, the inverter 142 closes and thus does not output a signal. Meanwhile, the inverter 144 opens and inverts the output signal of the inverter 143, and returns it to the inverter 143 and also outputs it to the inverter 145. Therefore, when the control signal MAE is negated, the signal levels of the match signal output line MLO and the All-Miss determination input AMI are held at their previous values.

FIG. 8 is an example of the All-invalid detection circuit 13. The All-invalid detection circuit 13 is a circuit that outputs the control signal AIF when all the valid cells VC indicate invalid. In other words, when all the entries are invalid, the control signal AIF is asserted. In FIG. 8, the All-invalid detection circuit 13 is illustrated as being configured of AND circuits connected in multiple stages, but other circuit configurations may be used as long as they can achieve the above function.

### Operation of this embodiment

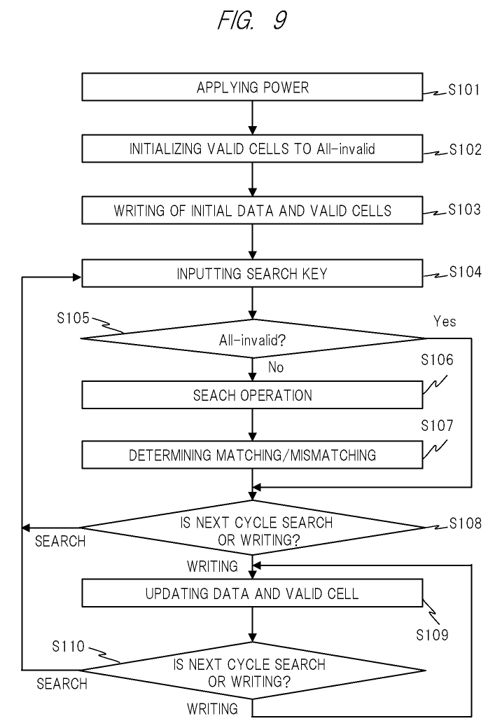

Next, the operation of the content addressable memory 1 configured as described above will be described with reference to the flowchart in FIG. 9. First, power is applied to the content addressable memory 1 (step S101). Next, the control unit 15 initializes all the valid cells VC to invalid (All-invalid) (step S102). This is because all data in the TCAM cells MC is invalid data immediately after power is applied. In step S102, the reset signal RT is output from the control unit 15 to initialize all the valid cells VC to an invalid state.

Next, writing of initial data and valid cells VC is performed (step S103). In step S103, the initial data is written to the TCAM cells MC of the cell array 12, and the valid cells VC corresponding to the entries to which the initial data has been written are set to valid.

Next, when a search key (search data) is input from the input/output circuit 11 (step S104), the All-invalid detection circuit 13 determines whether all the valid cells VC are invalid (All-invalid) (step S105). If the result of the determination in step S105 is All-invalid (step S105: Yes), the control signals PCE and SLE are not asserted and the process proceeds to step S108 without executing steps S106 and S107.

On the other hand, if the result of the determination in step S105 is not All-invalid (step S105: No), the control signals PCE and SLE are asserted and the process proceeds to step S106. Then, a search operation is performed using the search key input in step S104 (step S106), and matching or mismatching is determined (step S107). In other words, the value of the match line ML for each entry is output as the match signal output line MLO. Here, steps S104 to S107 are performed within one processing cycle. In this embodiment, one processing cycle is one cycle of the clock signal CLK.

Next, it is determined whether the next processing cycle is a search operation or a write operation (step S108). It is determined that the next processing cycle is the search operation when the control signal CMP indicating a search request is input to the control unit 15, and that the next processing cycle is the write operation when a control signal WEN indicating a write request is input to the control unit 15.

When it is determined in step S108 that the next processing cycle is the search operation, the process returns to step S104. On the other hand, when it is determined in step S108 that the next processing cycle is the write operation, the process proceeds to step S109. In step S109, data is written, and the valid cell VC corresponding to the data entry to which the data has been written is set to valid. Step S109 is executed within one processing cycle.

Next, it is determined whether the next processing cycle is a search operation or a write operation (step S110). The determination of search operation or write operation is the same as that in step S108. When it is determined in step S110 that the next processing cycle is the search operation, the process returns to step S104. On the other hand, when it is determined in step S110 that the next processing cycle is the write operation, the process returns to step S109.

Here, even if valid data is written to a data entry, the content addressable memory 1 may invalidate the data in order to ensure a writable region when the data in the data entry is no longer needed. Therefore, even after the initial data is written in the flowchart of FIG. 9, the All-invalid can be established in the determination in step S105. Also, the writing of the initial data in step S103 may be omitted. When the writing of the initial data in step S103 is omitted, the All-invalid is established in the determination in step S105 until valid data is written.

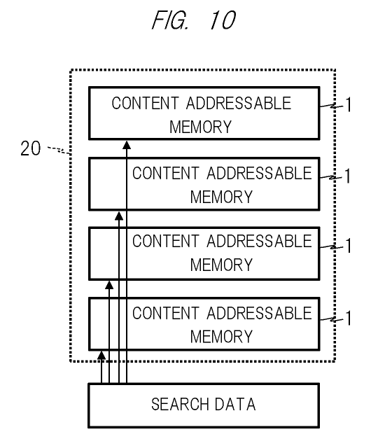

The content addressable memory 1 that operates in this way is preferably applied to the configuration in which it is divided into a plurality of content addressable memories as illustrated in FIG. 10. FIG. 10 is a schematic diagram of a semiconductor device 20 including a plurality of content addressable memories 1. In the configuration of FIG. 10, the same search data is input to each of the plurality of content addressable memories 1.

In the configuration of FIG. 10, the four content addressable memories 1 are handled from the outside as one memory with consecutive addresses. For example, it is possible to use it in such a way that valid data is stored sequentially starting from the bottommost content addressable memory 1 illustrated in FIG. 10. Therefore, there may be a state in which valid data is stored only in the bottommost content addressable memory 1 and the other content addressable memories 1 are all invalid. In this case, the search operation of the content addressable memories 1 that are all invalid can be stopped by the control signal AIF output by the All-invalid detection circuit 13.

With the above configuration, the content addressable memory 1 stops the search unit 10 when the All-invalid detection circuit 13, which detects that all the plurality of valid cells VC indicate invalid, detects the All-invalid. Therefore, it is possible to stop the search operation in units of the content addressable memories 1, making it possible to reduce the power consumption.

Furthermore, since the semiconductor device 20 has a plurality of content addressable memories 1 and the same search data is input to each of the plurality of content addressable memories 1, it is possible to use each content addressable memory 1 as a storage capacity capable of high-speed operation. This makes it possible to increase the speed of the semiconductor device 20 while reducing its power consumption.

### Second embodiment

Next, the second embodiment will be described. In the following, the description of the parts overlapping with the above-mentioned embodiment will be omitted in principle.

### Problems to be solved by this embodiment

The control signal AIF described in the first embodiment is a signal that stops the control signal PCE or the like asserted during the search operation according to the state of the valid cell VC. When rewriting of the valid cell VC is caused, the control signal AIF must reach the control unit 15 in the period between the data update and the next processing cycle. In other words, the control signal AIF must change from an asserted state to a negated state in the period between the data update and the next cycle. However, in the case of a chip (semiconductor device) in which the valid cells VC vary greatly, the next processing cycle may start before the control signal AIF is negated, causing a malfunction. Although such chips with large variations can be removed as defective by testing or the like, this leads to a decrease in yield. This embodiment deals with such variations in the valid cells VC.

### Circuit example of this embodiment

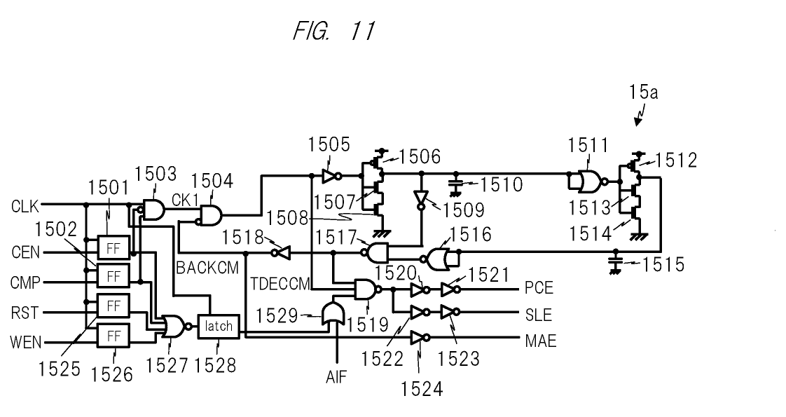

In this embodiment, the timing generation circuit 15a is partially modified. FIG. 11 illustrates the timing generation circuit 15a according to this embodiment. To the timing generation circuit 15a illustrated in FIG. 11, flip-flops 1525 and 1526, a NOR circuit 1527, a latch 1528, and an OR circuit 1529 are added relative to the circuit illustrated in FIG. 4.

The flip-flop 1525 takes in and outputs a control signal RST based on the clock signal CLK. The control signal RST is a reset signal. The flip-flop 1526 takes in and outputs the control signal WEN based on the clock signal CLK. As described in the first embodiment, the control signal WEN is a write request signal (write control signal).

The NOR circuit 1527 receives the output signals of the flip-flops 1501, 1502, 1525, and 1526 and outputs the result of NOR logic operation. The latch 1528 latches the output signal of the NOR circuit 1527 based on the clock signal CLK. The OR circuit 1529 receives the output signal of the latch 1528 and the control signal AIF and outputs the result of OR logic operation. The output of the OR circuit 1529 becomes the input signal of the NAND circuit 1519.

In the circuit illustrated in FIG. 11, the control signals (CEN, WEN, CMP, RST) input to the control unit 15 are held in the flip-flops, and the outputs of these flip-flops are bundled and latched to take the logical OR with the control signal AIF. In this way, the state of the content addressable memory 1 one processing cycle before can be referenced, and if it is the writing, a search is forcibly performed regardless of the control signal AIF. In other words, the latch 1528 functions as a holding unit that holds the control signal indicating a write request for one processing cycle. Then, when the latch 1528 holds the control signal indicating a write request, the timing generation circuit 15a operates the search unit 10 regardless of the result of the All-invalid detection circuit 13.

### Operation of this embodiment

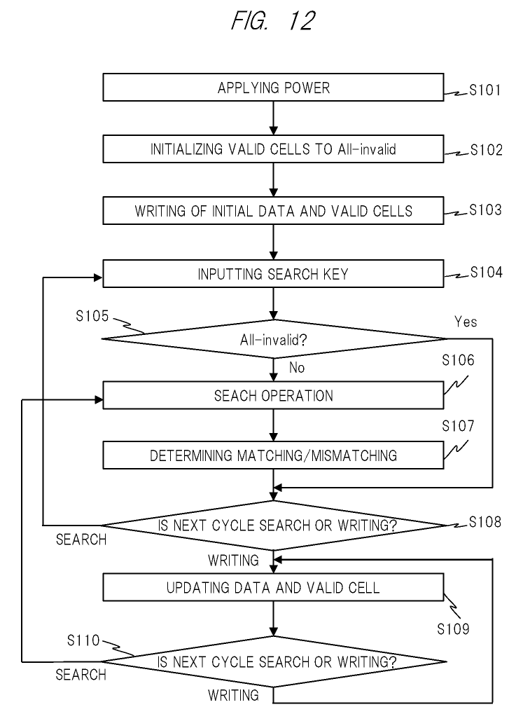

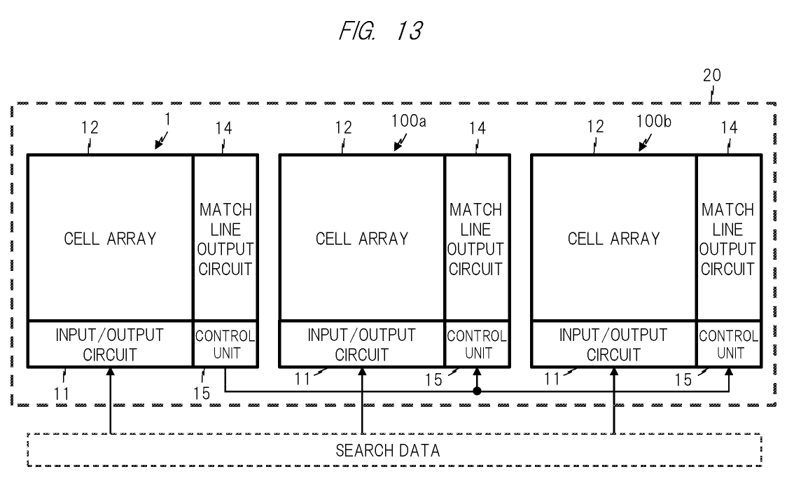

Next, the operation of the content addressable memory 1 configured as described above will be described with reference to the flowchart in FIG. 12. The flowchart illustrated in FIG. 12 differs from the flowchart illustrated in FIG. 9 in that the return destination when it is determined in step S110 that the next processing cycle is the search operation is step S106.

In other words, since the data and valid cell VC are updated in step S109, the previous processing cycle is the writing, and thus, when the search operation is to be performed in the next processing cycle, the search operation is performed without the determination of All-invalid. Namely, in the processing cycle next to the processing cycle in which valid is stored in the valid cell VC, the control unit 15 operates the search unit 10 regardless of the result of the All-invalid detection circuit 13.

With the above configuration, when the All-invalid detection circuit 13 stops the search unit 10, if the processing cycle next to the processing cycle in which writing has occurred in the cell array 12 is the search, the content addressable memory 1 performs the search regardless of the control signal AIF output by the All-invalid detection circuit 13. Therefore, by adding a circuit that is less likely to malfunction, even the chip (semiconductor device) in which the valid cells VC vary greatly can be stably operated. As a result, it is possible to improve the yield of the semiconductor device 20.

### Third embodiment

Next, the third embodiment will be described. In the following, the description of the parts overlapping with the above-mentioned embodiments will be omitted in principle.

A configuration of a content addressable memory in which the cell array is divided into a plurality of parts in the bit direction, and if all the entries in the preceding cell array are mismatched, the search operation of the following cell array is stopped has been proposed (see, for example, Japanese Unexamined Patent Application Publication No. 2023-114100). In this way, according to the result that all entries in the preceding cell array are mismatched, the mismatching for the entire content addressable memory can be determined without performing a search in the following cell array. In this embodiment, the content addressable memory 1 is applied to such a configuration.

FIG. 13 illustrates a schematic configuration of the semiconductor device 20 according to this embodiment. The semiconductor device 20 includes the content addressable memory 1 and content addressable memories 100a and 100b. In the configuration of FIG. 13, the stored data (data entries) are divided into a plurality of memory blocks along the column direction (bit direction) of the cell array. Namely, the content addressable memory 1 is the first block, and the content addressable memories 100a and 100b combined together form the second block. Also, the content addressable memories 100a and 100b each form a sub-block. Further, the content addressable memory 1 may be referred to as the master block, and the content addressable memories 100a and 100b may be referred to as the slave block.

The content addressable memory 1 including only the input/output circuit 11, the cell array 12, the match line output circuit 14, and the control unit 15 is illustrated in FIG. 13, but it has the same configuration as that illustrated in FIG. 2 and also includes the All-invalid detection circuit 13, the word line driver 16, and others.

The content addressable memories 100a and 100b have the same configuration as the content addressable memory 1. However, the All-invalid detection circuit 13, which is a feature of the content addressable memory 1, may not be provided, and the control function of the timing generation circuit 15a using the control signal AIF also may not be provided. In other words, in the content addressable memories 100a and 100b, the cell array 12 functions as a second cell array, and the input/output circuit 11, the match line output circuit 14, and others function as a second search unit.

In the semiconductor device 20 illustrated in FIG. 13, one data entry or search data is divided and correspondingly input to each of the content addressable memories 1, 100a, and 100b. For example, when the cell arrays 12 of the content addressable memories 1, 100a, and 100b are each 40 bits, 120 bits of data are divided into 40 bits each and stored as data entries at the same address of each cell array 12. Then, the search data is also divided into 40 bits each and input to each input/output circuit 11. Namely, the 40 bits stored in the content addressable memory 1 correspond to the first part, and the 80 bits stored in the content addressable memories 100a and 100b correspond to the second part. Further, of the 80 bits that correspond to the second part, the 40 bits stored in the content addressable memory 100a and the 40 bits stored in the content addressable memory 100b each correspond to the third part.

In the configuration illustrated in FIG. 13, the search operation of the master block is performed in the first processing cycle, and the search operation of the slave block is performed in the second processing cycle. When all the data entries are mismatched as a result of the search operation of the content addressable memory 1 which is the master block, it stops the search operation of the content addressable memories 100a and 100b, which are the slave blocks, to be performed in the next processing cycle.

In this case, the control unit 15 of the content addressable memory 1 detects that all the data entries in the cell array 12 are mismatched, and outputs a control signal to stop the slave block to the control unit 15 of each slave block (content addressable memory 100a and 100b). Specifically, with reference to the All-Miss determination input AMI illustrated in FIG. 7, when the All-Miss determination input AMI corresponding to all the match lines ML indicates the mismatching, the control signal to stop the above slave is output. In other words, when the search unit 10 determines that all the entries are mismatched, the control unit 15 stops the search operation of the second block.

In the configuration illustrated in FIG. 13, the second block is made up of two sub-blocks (content addressable memories 100a and 100b), but the number of sub-blocks may be three or more. Also, the second block does not need to be divided into sub-blocks.

With the above configuration, by using the content addressable memory 1 as the master block, it is possible to reduce the power consumption of the master block which operates frequently.

### Application example

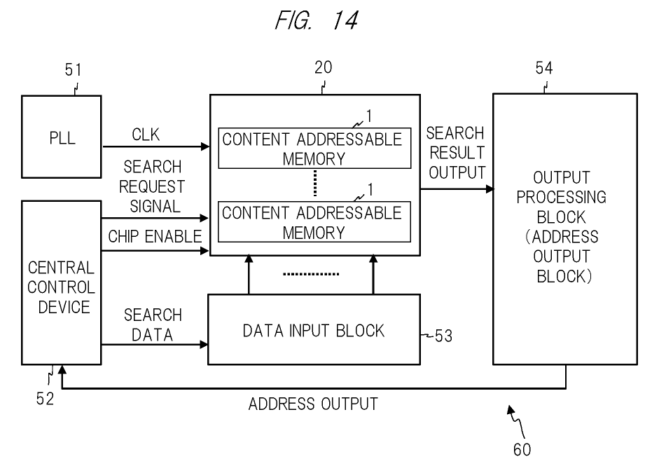

Finally, an application example of the above-mentioned embodiments will be described. The semiconductor device 20 illustrated in FIG. 10 and others can be used for the address search and the access control in a router for a network such as Internet. FIG. 14 illustrates an example of an address search system in a router using the semiconductor device 20.

An address search system 60 illustrated in FIG. 14 includes the semiconductor device 20, a PLL 51, a central control device 52, a data input block 53, and an output processing block 54.

The semiconductor device 20 includes a plurality of content addressable memories 1 as illustrated in, for example, FIG. 10. The same search data is input to each of the plurality of content addressable memories 1.

The PLL 51 is a well-known phase-locked loop circuit, and outputs the clock signal CLK to the semiconductor device 20. The central control device 52 outputs a search request signal to the semiconductor device 20. Also, the central control device 52 outputs search data to the data input block 53. The data input block 53 outputs the search data input from the central control device 52 to the semiconductor device 20. Based on the search result output from the semiconductor device 20, the output processing block 54 outputs the matching (hit) address to the central control device 52.

The address search system 60 illustrated in FIG. 14 stores network data such as IP addresses in advance. Then, after starting the search operation, the central control device 52 inputs a search request signal to the semiconductor device 20 and simultaneously inputs the data to be searched from the data input block 53 to the semiconductor device 20. The semiconductor device 20 compares the data stored in the cell array 12 with the data to be searched, and transmits all matching addresses to the output processing block 54. The output processing block 54 outputs the corresponding address with the highest priority to the central control device 52. The priority may be determined by address, for example, by placing information with high priority at the lower address of the cell array, or may be determined by providing a priority encoder or the like.

In the foregoing, the invention made by the inventors of this application has been specifically described on the basis of the embodiments, but it goes without saying that the present invention is not limited to the embodiments described above and various modifications can be made within the range not departing from the gist thereof.

What is claimed is:

1. A content addressable memory comprising:
a cell array capable of storing a plurality of data entries;
a valid cell provided for each of the data entries and configured to store information indicating valid or invalid of the data entry;
an invalid detection unit configured to detect that the information all indicates invalid;
a first search unit configured to determine matching or mismatching between the plurality of data entries and search data input from outside; and
a control unit configured to stop the first search unit when the invalid detection unit detects that the information all indicates invalid.

2. The content addressable memory according to claim 1,
wherein the invalid detection unit outputs an invalid control signal indicating that the information is all invalid, and
wherein the control unit stops the input of the search data based on the invalid control signal.

3. The content addressable memory according to claim 1,
wherein the control unit operates the first search unit regardless of a result of the invalid detection unit in a processing cycle next to a processing cycle in which information indicating valid is stored in the valid cell.

4. The content addressable memory according to claim 3,
wherein the control unit includes a holding unit configured to hold a write control signal indicating a write request for one processing cycle, and
wherein the control unit operates the first search unit regardless of the result of the invalid detection unit when the holding unit holds the write control signal.

5. A semiconductor device plurally including the content addressable memory according to claim 1,
wherein the same search data is input to each of the plurality of content addressable memories.

6. A semiconductor device comprising:
a first block composed of the content addressable memory according to claim 1 and configured to store a first part of bit strings constituting the data entries; and
a second block configured to store a second part of the bit strings other than the first part,
wherein the search data has a same number of bits as the bit strings constituting the data entries,
wherein the second block includes a second cell array capable of plurally storing the second part and a second search unit configured to determine matching or mismatching between the plurality of second parts and a part of the search data corresponding to the second part,
wherein a part of the bit strings constituting the search data corresponding to the first part is input to the first block, and
wherein the control unit stops a search operation of the second block when the first search unit determines that all the data entries are mismatched.

7. The semiconductor device according to claim 6,
wherein the second block is made up of a plurality of sub-blocks which store each of a plurality of third parts constituting the second part.
